(19) United States
(12) Patent Application Publication
(10) Pub. No.: US 2012/0043222 A1
(43) Pub. Date: Feb. 23, 2012

(54) COATING METHOD FOR FORMING PATTERN ON WORKPIECE

(75) Inventor: CHUNG-PEI WANG, Tu-Cheng (TW)

(73) Assignee: HON HAI PRECISION INDUSTRY CO., LTD., Tu-Cheng (TW)

(21) Appl. No.: 12/975,377

(22) Filed: Dec. 22, 2010

(30) Foreign Application Priority Data
Aug. 18, 2010 (TW) 99127502

(51) Int. Cl. C25F 3/02; C23C 16/06; C23C 16/44; C23C 16/04

(52) U.S. Cl. 205/640; 427/248.1; 427/250; 427/127

(57) ABSTRACT

A coating method for forming a pattern on a workpiece includes: providing a workpiece constituting a surface; forming a coating layer over the surface using a physical vapor deposition method; providing a mask including a through hole having a shape conforming to a predetermined pattern; attaching the mask to the surface such that a portion of the coating layer is exposed through the through hole, the coating layer consisting of the exposed portion and an unwanted portion surrounding the exposed portion; forming a shielding layer on the exposed portion of the coating layer in the through hole; removing the mask; removing the unwanted portion of the coating layer; and removing the shielding layer to obtain the exposed portion having the predetermined pattern.

### BACKGROUND

1. Technical Field

The present disclosure relates to coating methods, and particularly to a coating method for forming a pattern on a workpiece, for example, an outer shell of a mobile phone.

2. Description of Related Art

Metal or metal oxide coatings can be applied to a predetermined area of a workpiece by physical vapor deposition (PVD) methods or chemical vapor deposition (CVD) methods. A shielding sheet covers the non-predetermined area so that the metal or metal oxide materials will be only coated on the predetermined area. However, the disadvantage of using PVD or CVD methods only is that the shielding sheet is usually too thick; some metal or metal oxide coatings may be deposited on the edges of the shielding sheet and on the edges of the predetermined area. Therefore, the edges of the predetermined area may be blurred, and the thickness of the coat may not be uniform.

What is needed, therefore, is a coating method for forming pattern on workpiece, which can overcome the above shortcomings.

### BRIEF DESCRIPTION OF THE DRAWINGS

Many aspects of the present coating method for forming pattern on workpiece can be better understood with reference to the following drawings. The components in the drawings are not necessarily drawn to scale, the emphasis instead being placed upon clearly illustrating the principles of the present coating method for forming patterns. Moreover, in the drawings, like reference numerals designate corresponding parts throughout the views.

FIG. 1 is a schematic view of a workpiece coated with a coating layer.

FIG. 2 is a schematic view of the workpiece shown in FIG. 1 covered by a mask and coated with a shielding layer through a through hole of the mask.

FIG. 3 is a schematic view of the workpiece shown in FIG. 2 with the coating layer except a part protected by the shielding layer removed.

FIG. 4 is a schematic view of the workpiece shown in FIG. 3 with a pattern.

### DETAILED DESCRIPTION

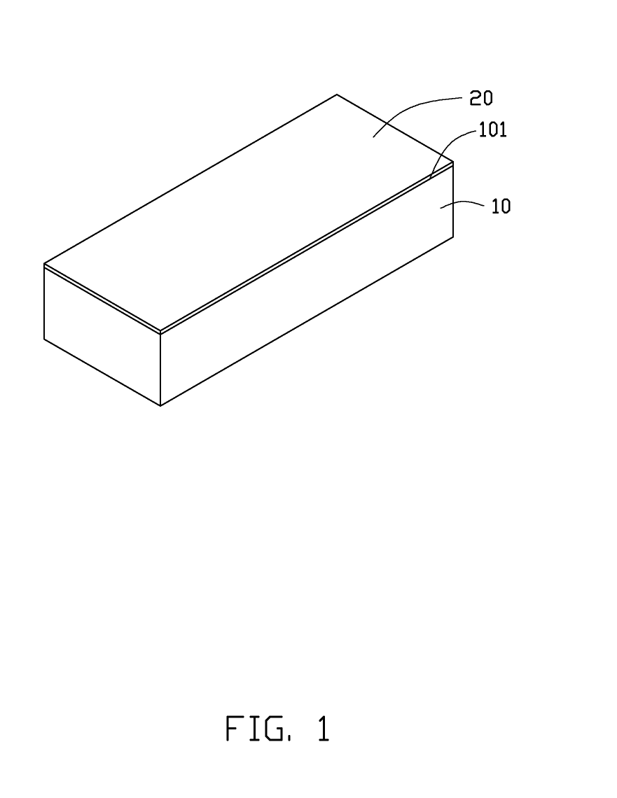

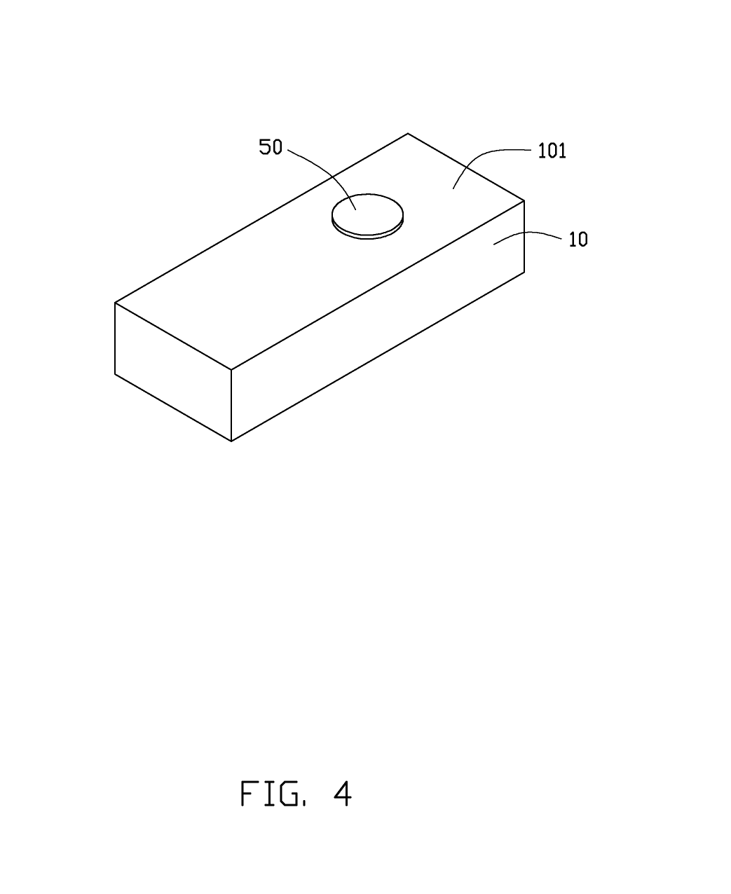

Referring to the FIG. 1, a workpiece 10 constituting an external surface 101 is subjected to a coating step. The workpiece 10 is made of ferromagnetic materials, for example iron, nickel, or cobalt. The surface 101 is flat. A predetermined pattern 50 (shown in FIG. 4) will be formed on the surface 101. The area of the predetermined pattern 50 is smaller than that of the surface 101. The predetermined pattern 50 in this embodiment is a circular shape.

In a first step, a coating layer 20 is deposited over the entire surface 101. The predetermined pattern 50 may be a logo, or a trademark. The coating layer 20 may be coated on the surface 101 by PVD method. The coating layer 20 may include a single film or a multi-layer film. The material of the coating layer 20 may be metal, metal oxide, or plastic.

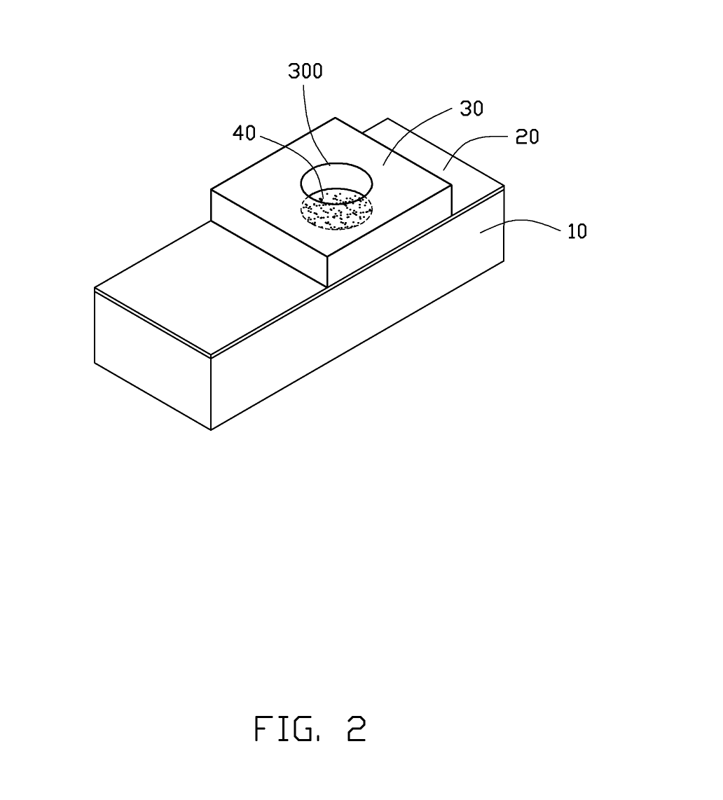

In a second step, referring to the FIG. 2, a mask 30 is applied to the coating layer 20. The mask 30 shields the coating layer 20 except the area of the predetermined pattern 50. The mask 30 is made of magnetic materials, for example magnet, or permanent magnet. The mask 30 includes a through hole 300 that has a shape conforming to the predetermined pattern 50. The area of predetermined pattern 50 is exposed due to the through hole 300. Because the workpiece 10 is made of ferromagnetic materials, it is easy to attach the mask 30 to the workpiece 10 firmly. The mask 30 is required to shield the surface 101 as much as possible except the area of the predetermined pattern 50. Thus, the coating layer 20 consists of the exposed portion and unwanted portion surrounding the exposed portion. The form of the mask 30 is not limited to the form shown in FIG. 2.

In a third step, a shielding layer 40 is deposited on the exposed portion of the coating layer 20 in the through hole 300. That is, the shielding layer 40 has the same pattern as the predetermined pattern 50. The material of the shielding layer 40 may be ink or photoresist.

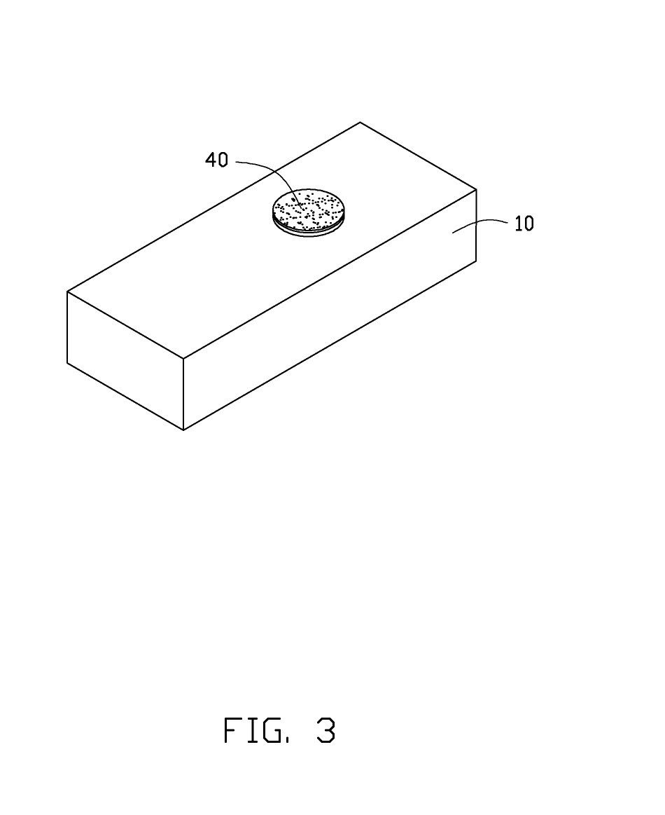

In a fourth step, referring to the FIG. 3, the mask 30 is removed after the shielding layer 40 is deposited on the surface 101. The unwanted portion of the coating layer 20 is removed by electrochemical machining method. Because the shielding layer 40 is made of the ink or photoresist that does not react with materials used in the electrochemical machining method, the shielding layer 40 thus protects the coating layer 20 under the shielding layer 40.

Next, referring to the FIG. 4, after the unwanted portion of the coating layer 20 is removed, the shielding layer 40 is removed according to the properties of the material. If the shielding layer 40 is made of an ink, alkaline solution, for example sodium hydroxide (NaOH) solution, may be used to remove the shielding layer 40. The shielding layer 40 made of photoresist may be removed using a photoresist developer. Because the alkaline solution or photoresist developer does not act on the material of the coating layer 20, the coating layer 20 under the shielding layer 40 is kept; therefore, a predetermined pattern 50 is shown.

The predetermined pattern 50 is formed actually in the first step of coating the coating layer 20. Because the coating layer 20 is coated on the entire surface 101, the thickness of the coating layer 20 is uniform. The area of the predetermined pattern 50 is kept protecting by the shielding layer 40, so the predetermined pattern 50 will not be destroyed or blurred by the other procedures.

It is understood that the above-described embodiments are intended to illustrate rather than limit the disclosure. Variations may be made to the embodiments without departing from the spirit of the disclosure. Accordingly, it is appropriate that the appended claims be construed broadly and in a manner consistent with the scope of the disclosure.

What is claimed is:

1. A coating method for forming a pattern on a workpiece comprising:
providing a workpiece having a surface;
forming a coating layer over the surface using a physical vapor deposition method;
providing a mask including a through hole having a shape conforming to a predetermined pattern;
attaching the mask to the surface such that a portion of the coating layer is exposed through the through hole, the coating layer consisting of the exposed portion and an unwanted portion surrounding the exposed portion;
forming a shielding layer on the exposed portion of the coating layer in the through hole;
removing the mask;
removing the unwanted portion of the coating layer; and
removing the shielding layer to obtain the exposed portion having the predetermined pattern.

2. The coating method for forming a pattern according to claim 1, wherein the unwanted portion of the coating layer is removed using an electrochemical machining method.

3. The coating method for forming a pattern according to claim 1, wherein the shielding layer is made of ink.

4. The coating method for forming a pattern according to claim 1, wherein the shielding layer is made of photoresist.

5. The coating method for forming a pattern according to claim 4, wherein the shielding layer is removed using a photoresist developer.

6. The coating method for forming a pattern according to claim 1, wherein the workpiece is made of ferromagnetic material, and the mask is made of magnetic material.

7. The coating method for forming a pattern according to claim 1, wherein the coating layer is made of metal or metal oxides.
